(19) United States
(12) Patent Application Publication
(10) Pub. No.: US 2014/0242798 A1
(43) Pub. Date: Aug. 28, 2014

(54) POLISHING COMPOSITION

(71) Applicant: FUJIMI INCORPORATION, Aichi (JP)

(72) Inventors: Yoshihiro Izawa, Kiyosu-shi (JP); Yukinobu Yoshizaki, Kiyosu-shi (JP)

(73) Assignee: FUJIMI INCORPORATION, Kiyosu-shi, Aichi (JP)

(21) Appl. No.: 14/346,923

(22) PCT Filed: Sep. 28, 2012
(86) PCT No.: PCT/JP2012/075051

§ 371 Date: Mar. 24, 2014

(30) Foreign Application Priority Data
Sep. 30, 2011 (JP) 2011-218721

(51) Int. Cl. C09G 1/02; H01L 45/00

(52) U.S. Cl. CPC C09G 1/02; H01L 45/16
USPC 438/693; 252/79.1; 558/27; 558/186; 562/45; 564/291; 564/282; 536/123.1; 558/435; 536/56; 564/197; 526/312; 526/272; 526/310

(57) ABSTRACT

A polishing composition of the present invention is used for polishing an object containing a phase-change alloy and is characterized by containing an ionic additive. Examples of the ionic additive include a cationic surfactant, an anionic surfactant, an amphoteric surfactant, and a cationic water-soluble polymer.

### TECHNICAL FIELD

The present invention relates to a polishing composition suitable for polishing an object containing a phase-change alloy.

### BACKGROUND ART

A phase-change material (PCM), which can be electrically switched between an insulative amorphous phase and a conductive crystalline phase, for an electronic memory application is utilized for a PRAM (phase-change random access memory) device (also known as an ovonic memory device or a PCRAM device). Examples of typical phase-change materials suitable for this application include a combination of an element of VIB group (chalcogenide, for example, Te or Po) and VB group (for example, Sb) of the periodic table and one or more metal elements such as In, Ge, Ga, Sn, and Ag. A particularly useful phase-change material is a germanium (Ge)-antimony (Sb)-tellurium (Te) alloy (GST alloy). The physical conditions of these materials may reversibly change depending on heating/cooling rate, temperature, and time. Examples of other useful phase-change alloys include indium antimonite (InSb). The memory information in the PRAM device is stored with minimizing loss by the conduction characteristics of different physical phases or states.

Chemical mechanical polishing (CMP) is known as a method for polishing a metal-containing surface of a semiconductor substrate (for example, integrated circuit). The polishing composition used in CMP typically contains abrasive grains, an oxidizing agent, and a complexing agent to effectively polish the surface by the etching action.

CMP can be utilized for manufacturing a memory device that uses a phase-change material. However, unlike a conventional metal layer composed of a single component such as copper (Cu) and tungsten (W), a plurality of elements such as sulfur (S), cerium (Ce), germanium (Ge), antimony (Sb), tellurium (Te), silver (Ag), indium (In), tin (Sn), and gallium (Ga) are mixed in a phase-change material at a specific ratio that allows reversible phase-change between a crystalline phase and an amorphous phase. For this reason, the physical properties of many phase-change materials (for example, GST) are different from the physical properties of conventional metal layer materials, for example, in that they are softer than other materials used in a PCM chip. Therefore, it is difficult to apply the conventional polishing composition for polishing metal-containing surfaces as it is to the polishing of a phase-change material.

In such a situation, various investigations have been performed on the polishing composition suitable for polishing an object containing a phase-change alloy. For example, Patent Documents 1 and 2 disclose a polishing composition for polishing an object containing a phase-change alloy, the composition containing abrasive grains, a complexing agent, water, and optionally an oxidizing agent. The polishing compositions disclosed in these documents are intended to improve conventional typical polishing compositions used for polishing metal-containing surfaces thereby to reduce a surface defect and a residue of a phase-change material, but they have a problem that the etching rate of the phase-change alloy is too high. In order to reduce the etching rate, it is effective to reduce the concentration of the oxidizing agent and complexing agent contributing to etching. However, if the concentration of the oxidizing agent or complexing agent in the polishing composition is reduced, a new problem occurs that the amount of a polishing by-product or an organic residue adhering to a polished object increases. It should be noted that the polishing by-product includes polishing debris to be produced during polishing, and that the organic residue refers to foreign matter containing carbon derived from a polishing pad, a polishing apparatus, a cleaning brush, or a polishing composition. The polishing by-product and organic residue are also hereinafter inclusively referred to as “defective foreign matter”.

### PRIOR ART DOCUMENTS

Patent Document 1: Japanese National Phase Laid-Open Patent Publication No. 2010-534934
Patent Document 2: Japanese Laid-Open Patent Publication No. 2009-525615

### SUMMARY OF THE INVENTION

### Problems that the Invention is to Solve

Accordingly, it is an objective of the present invention to provide a polishing composition that can be suitably used for polishing an object containing a phase-change alloy, particularly to provide a polishing composition that can prevent occurrence of a polishing by-product and an organic residue.

### Means for Solving the Problems

To achieve the foregoing objective and in accordance with one aspect of the present invention, a polishing composition to be used for polishing an object containing a phase-change alloy, such as a GST alloy, is provided that contains an ionic additive.

In one embodiment, the ionic additive is one or more selected from the group consisting of a cationic surfactant, an anionic surfactant, and an amphoteric surfactant.

The ionic additive is preferably a cationic water-soluble polymer.

The polishing composition contains the ionic additive in a concentration of preferably 0.0001 to 10% by mass.

Another aspect of the present invention provides a polishing method for polishing a surface of an object containing a phase-change alloy with the polishing composition according to the above aspect.

Yet another aspect of the present invention provides a method for producing a phase-change device that includes polishing a surface of an object containing a phase-change alloy with the polishing composition according to the above aspect.

### Effects of the Invention

The present invention provides a polishing composition that can be suitably used for polishing an object containing a phase-change alloy, particularly a polishing composition that is effective for the reduction of a polishing by-product and an organic residue.

### MODES FOR CARRYING OUT THE INVENTION

Hereinafter, one embodiment of the present invention will be described.

A polishing composition according to the present embodiment is used for polishing an object containing a phase-change alloy, specifically polishing a surface of an object containing a phase change-alloy to produce a phase-change device. The phase-change alloy is utilized as a material that can be electrically switched between an insulative amorphous phase and a conductive crystalline phase for an electronic memory application in a PRAM (phase-change random access memory) device (also known as an ovonic memory device or a PCRAM device). Examples of the phase-change alloy suitable for this application include a combination of an element of VIB group (chalcogenide, for example, Te or Po) and VB group (for example, Sb) of the periodic table and one or more metal elements such as In, Ge, Ga, Sn, and Ag. A particularly useful phase-change material is a germanium (Ge)-antimony (Sb)-tellurium (Te) alloy (GST alloy).

### (Ionic Additive)

The polishing composition of the present embodiment contains an ionic additive. The ionic additive refers to a substance having a positive or negative potential in an aqueous solution and being capable of changing the potential, specifically the zeta potential, of an object to be polished or defective foreign matter. It is estimated that the ionic additive is bound or adsorbs to the surface of both or either of a phase-change alloy and defective foreign matter to thereby adjust the charges of the phase-change alloy surface and the defective foreign matter surface to the same sign (that is, both carry positive charges or negative charges), and that a repulsive force to act between the phase-change alloy surface and the defective foreign matter surface is thus caused. That is, although details are unknown, the ionic additive is estimated to act according to any of the following three cases.

(1) The ionic additive is bound or adheres to both the phase-change alloy surface and the defective foreign matter surface to cause a repulsive force between the phase-change alloy surface and the defective foreign matter surface.

(2) The ionic additive is bound or adheres mainly to the phase-change alloy surface to give a repulsive force to the phase-change alloy surface acting against the charge that the defective foreign matter originally has.

(3) The ionic additive is bound or adheres mainly to the defective foreign matter to give a repulsive force to the defective foreign matter acting against the charge that the phase-change alloy originally has.

In the case where the ionic additive that adsorbs or adheres to the phase-change alloy surface is selected to be used, the type and the content of metals constituting the phase-change alloy are preferably taken into consideration. That is, it is preferred to select an ionic additive to be used that imparts larger amount of charge per unit area to a metal contained at a higher content and imparts less amount of charge per unit area to a metal contained at a lower content, among the metals constituting the phase-change alloy. For example, in the case of a GST alloy in which the ratio of the mass of Ge, Sb, and Te is 2:2:5, it is preferred to select an ionic additive to be used that imparts larger amount of charge per unit area to Te, which is contained at a higher content, and imparts less amount of charge per unit area to Ge and Sb, which are contained at a lower content.

In the case where the ionic additive that adsorbs or adheres to the defective foreign matter surface is selected to be used, the components of the defective foreign matter are preferably taken into consideration. For example, an organic residue derived from a polishing pad made of polyurethane has a positive charge at the vicinity of a pH of 3.0. An organic residue derived from a cleaning brush made of polyvinyl alcohol has a negative charge at the vicinity of a pH of 3.0. In the case where the components of an organic residue as the defective foreign matter is known, if an ionic additive having an opposite charge to the charge of the organic residue is selected and used, an attraction force occurs between the ionic additive and the organic residue, and the ionic additive, in other words, the charge, can be efficiently imparted to the organic residue surface. In the case where the defective foreign matter is a polishing by-product, the type and the content of metals constituting the phase-change alloy are preferably taken into consideration as described above.

The ionic additive is a compound having a charge, and specific examples thereof include a cationic surfactant, an anionic surfactant, an amphoteric surfactant, and a water-soluble polymer having a charge. Examples of the cationic surfactant include a quaternary ammonium salt surfactant, an alkylamine salt surfactant, and a pyridine ring compound surfactant. More specific examples thereof include a tetramethylammonium salt, a tetrabutylammonium salt, a dodecyl dimethyl benzyl ammonium salt, an alkyl trimethyl ammonium salt, an alkyl dimethyl ammonium salt, an alkyl benzyl dimethyl ammonium salt, a monoalkyl amine salt, a dialkyl amine salt, a trialkyl amine salt, a fatty acid amidoamine, and an alkyl pyridinium salt. Examples of the anionic surfactant include a carboxylic acid surfactant, a sulfonic acid surfactant, a sulfate surfactant, and a phosphate surfactant. More specific examples thereof include coconut oil fatty acid sarcosine triethanolamine, a coconut oil fatty acid methyltaurine salt an aliphatic monocarboxylate, an alkylbenzene sulfonate, an alkane sulfonate, an α-olefin sulfonate, a polyoxyethylene alkyl ether sulfate, an alkyl sulfate, a polyoxyethylene alkyl ether phosphate, and an alkyl phosphate. Examples of the amphoteric surfactant include an alkyl betaine and an alkyl amine oxide. Specific examples of the water-soluble polymer having a cationic charge include polysaccharides such as chitosan and a cation-modified hydroxyethyl cellulose, a polyalkylene imine, a polyalkylene polyamine, a polyvinyl amine, a polyamine-epichlorohydrin condensate, a cationic polyacrylamide, a poly(diallyldimethylammonium salt), and a diallylamine salt-acrylamide polymer. Specific examples of the water-soluble polymer having an anionic charge include a polyacrylate, an ammonium salt of a styrene-maleic acid copolymer. The repulsive force acting between the phase-change alloy surface and the defective foreign matter surface increases as the absolute value of the charge to be given is increased. It is preferred to select the ionic additive from the point of view that polishing and etching are not affected and the chemical or physical adsorbability to the phase-change alloy and the defective foreign matter is high. From such a point of view, when the phase-change alloy surface and the defective foreign matter surface have a negative charge, a cationic water-soluble polymer having many polar groups is preferred, and in particular, a polyalkylene polyamine is more preferred. Further, when the phase-change alloy surface and the defective foreign matter surface have a positive charge, an anionic surfactant or an anionic water-soluble polymer is preferred, and in particular, a polyoxyethylene lauryl ether phosphate ester is more preferred.

The molecular weight of the ionic additive is preferably 100,000 or less, more preferably 10,000 or less. The steric hindrance of the ionic additive on the surface of the phase-change alloy and the defective foreign matter decreases as the molecular weight of the ionic additive decreases. As a result, the charge can be efficiently imparted to cause the repulsive force to easily act, and therefore the defective foreign matter is effectively reduced.

The content of the ionic additive in the polishing composition is preferably 0.001% by mass or more, more preferably 0.01% by mass or more. The probability that the ionic additive will be bound or adsorb to the surface of the phase-change alloy and the defective foreign matter increases as the content of the ionic additive increases. As a result, the charge can be efficiently imparted to cause the repulsive force to easily act, and therefore the defective foreign matter is effectively reduced.

### (Abrasive Grains)

The polishing composition may contain abrasive grains. The abrasive grains may be any of inorganic particles, organic particles, and organic-inorganic composite particles. Specific examples of the inorganic particles include particles composed of metal oxides, such as silica, alumina, ceria, and titania, silicon nitride particles, silicon carbide particles, and boron nitride particles. Specific examples of the organic particles include poly(methyl methacrylate) (PMMA) particles. Among them, silica particles are preferred, and particularly preferred is colloidal silica.

The abrasive grains may be surface-modified. Since common colloidal silica has a value of zeta potential of close to zero under acidic conditions, the silica particles do not electrically repel each other to easily cause aggregation under acidic conditions. On the other hand, abrasive grains which are surface-modified so that the zeta potential may have a relatively large positive or negative value even under acidic conditions strongly repel each other even under acidic conditions and are satisfactorily dispersed. As a result, the storage stability of the polishing composition is improved. Such surface-modified abrasive grains can be obtained, for example, by mixing a metal such as aluminum, titanium, and zirconium or an oxide thereof with abrasive grains to allow the surface of the abrasive grains to be doped with the metal or oxide thereof. Alternatively, the surface of the abrasive grains may be modified with a sulfonic acid or a phosphonic acid by using a silane coupling agent having an amino group.

In any of the above cases, when the abrasive grains are added, the potential possessed by the abrasive grains preferably has the same sign as the potential possessed by the ionic additive. When the charge possessed by the abrasive grains has the opposite sign to the charge possessed by the ionic additive, the abrasive grains may aggregate through the ionic additive.

The content of the abrasive grains in the polishing composition is preferably 0.01% by mass or more, more preferably 0.05% by mass or more, further preferably 0.1% by mass or more. As the content of the abrasive grains increases, there is an advantage of increasing the removal rate of the phase-change alloy by the polishing composition.

Further, the content of the abrasive grains in the polishing composition is preferably 20% by mass or less, more preferably 15% by mass or less, further preferably 10% by mass or less. As the content of the abrasive grains decreases, the material cost of the polishing composition is reduced, and the aggregation of the abrasive grains is less likely to occur. Further, a polished surface with few surface defects is easily obtained by polishing the phase-change alloy with the polishing composition.

The average primary particle size of the abrasive grains is preferably 5 nm or more, more preferably 7 nm or more, further preferably 10 nm or more. As the average primary particle size of the abrasive grains increases, there is an advantage of increasing the removal rate of the phase-change alloy by the polishing composition. The value of the average primary particle size of the abrasive grains can be calculated, for example, based on the specific surface area of the abrasive grains measured by the BET method.

Further, the average primary particle size of the abrasive grains is preferably 100 nm or less, more preferably 90 nm or less, further preferably 80 nm or less. As the average primary particle size of the abrasive grains decreases, a polished surface with few surface defects is easily obtained by polishing the phase-change alloy with the polishing composition.

The average secondary particle size of the abrasive grains is preferably 150 nm or less, more preferably 120 nm or less, further preferably 100 nm or less. The value of the average secondary particle size of the abrasive grains can be measured, for example, by a laser light scattering method.

The average degree of association of the abrasive grains, which is a calculated value obtained by dividing the value of the average secondary particle size of the abrasive grains by the value of the average primary particle size thereof, is preferably 1.2 or more, more preferably 1.5 or more. As the average degree of association of the abrasive grains increases, there is an advantage of increasing the removal rate of the phase-change alloy by the polishing composition.

The average degree of association of the abrasive grains is preferably 4 or less, more preferably 3 or less, further preferably 2 or less. As the average degree of association of the abrasive grains decreases, a polished surface with few surface defects is easily obtained by polishing the phase-change alloy with the polishing composition.

### (pH of Polishing Composition and pH Adjuster)

The pH of the polishing composition is preferably 7 or less, more preferably 5 or less, further preferably 3 or less. As the pH of the polishing composition decreases, the etching of the phase-change alloy by the polishing composition is harder to occur, and as a result, the occurrence of surface defects is further suppressed.

A pH adjuster may be used for adjusting the pH of the polishing composition to a desired value. The pH adjuster to be used may be any of acid and alkali, and may be any of an inorganic compound and an organic compound.

### (Oxidizing Agent)

The polishing composition may contain an oxidizing agent. The oxidizing agent has an action of oxidizing the surface of an object to be polished. There is an effect of increasing the polishing rate of the phase-change alloy by the polishing composition when the oxidizing agent is added to the polishing composition. However, when the phase-change alloy is polished with a conventional typical polishing composition to be used for polishing a metal-containing surface, the phase-change alloy tends to be excessively polished. This is probably because the characteristics of the phase-change alloy are different from the characteristics of a metallic material such as copper commonly used in a semiconductor device.

The content of the oxidizing agent in the polishing composition is preferably 0.1% by mass or more, more preferably 0.3% by mass or more. The occurrence of an organic residue is suppressed as the content of the oxidizing agent increases.

The content of the oxidizing agent in the polishing composition is preferably 10% by mass or less, more preferably 5% by mass or less. As the content of the oxidizing agent decreases, excessive oxidation of the phase-change alloy by the oxidizing agent is harder to occur. Therefore, excessive polishing of the phase-change alloy is suppressed.

Examples of the oxidizing agent that can be used include peroxides. Specific examples of the peroxides include hydrogen peroxide, peracetic acid, percarbonates, urea peroxide, perchloric acid, and persulfates, such as sodium persulfate, potassium persulfate, and ammonium persulfate. Among them, persulfates and hydrogen peroxide are preferred from the point of view of the polishing rate, and hydrogen peroxide is particularly preferred from the point of view of the stability in an aqueous solution and the environmental load.

### (Complexing Agent)

The polishing composition may contain a complexing agent. The complexing agent has the effect of chemically etching the surface of the phase-change alloy and thus increasing the polishing rate of the phase-change alloy by the polishing composition. However, when the phase-change alloy is polished with a conventional typical polishing composition to be used for polishing a metal-containing surface, excessive etching of the phase-change alloy may occur, and as a result, the phase-change alloy tends to be excessively polished. This is probably because the characteristics of the phase-change alloy are different from the characteristics of a metallic material such as copper commonly used in a semiconductor device.

The content of the complexing agent in the polishing composition is preferably 0.01% by mass or more, more preferably 0.1% by mass or more. Since the etching effect of the complexing agent on the phase-change alloy increases as the content of the complexing agent increases, the polishing rate of the phase-change alloy by the polishing composition increases.

The content of the complexing agent in the polishing composition is preferably 10% by mass or less, more preferably 1% by mass or less. As the content of the complexing agent decreases, excessive etching of the phase-change alloy by the complexing agent is harder to occur. Therefore, excessive polishing of the phase-change alloy is suppressed.

Examples of the complexing agent that can be used include inorganic acids, organic acids, and amino acids. Specific examples of the inorganic acids include sulfuric acid, nitric acid, boric acid, carbonic acid, hypophosphorous acid, phosphorous acid, and phosphoric acid. Specific examples of the organic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, and lactic acid. Organic sulfonic acids, such as methanesulfonic acid, ethanesulfonic acid, and isethionic acid, can also be used. A salt, such as an ammonium salt and an alkali metal salt, of an inorganic acid or an organic acid may be used instead of an inorganic acid or an organic acid or in combination with an inorganic acid or an organic acid. Specific examples of the amino acids include glycine, α-alanine, β-alanine, N-methylglycine, N,N-dimethylglycine, 2-aminobutyric acid, norvaline, valine, leucine, norleucine, isoleucine, phenylalanine, proline, sarcosine, ornithine, lysine, taurine, serine, threonine, homoserine, tyrosine, vicine, tricine, 3,5-diiodo-tyrosine, β-(3,4-dihydroxyphenyl)-alanine, thyroxine, 4-hydroxy-proline, cysteine, methionine, ethionine, lanthionine, cystathionine, cystine, cysteic acid, aspartic acid, glutamic acid, S-(carboxymethyl)-cysteine, 4-aminobutyric acid, asparagine, glutamine, azaserine, arginine, canavanine, citrulline, δ-hydroxy-lysine, creatine, histidine, 1-methyl-histidine, 3-methyl-histidine, tryptophan, and iminodiacetic acid. Among them, glycine, alanine, iminodiacetic acid, malic acid, tartaric acid, citric acid, glycolic acid, and isethionic acid, or ammonium salts or alkali metal salts thereof are preferred as a complexing agent from the point of view of increasing the polishing rate.

### (Metal Corrosion Inhibitor)

The polishing composition may contain a metal corrosion inhibitor. When the metal corrosion inhibitor is added to the polishing composition, there is an effect of further decreasing the occurrence of surface defects such as dishing in the phase-change alloy after polishing with the polishing composition. In addition, when the polishing composition contains the oxidizing agent and/or the complexing agent, the metal corrosion inhibitor relieves the oxidation of the phase-change alloy surface by the oxidizing agent and also reacts with metal ions, which are produced by the oxidation of a metal of the phase-change alloy surface by the oxidizing agent, to produce an insoluble complex. As a result, the etching of the phase-change alloy by the complexing agent is suppressed, and excessive polishing of the phase-change alloy is suppressed.

Although the type of the metal corrosion inhibitor that can be used is not particularly limited, a heterocyclic compound is preferred. The number of members in heterocyclic rings in the heterocyclic compound is not particularly limited. The heterocyclic compound may be a monocyclic compound or a polycyclic compound having a condensed ring.

Specific examples of the heterocyclic compound as a metal corrosion inhibitor include nitrogen-containing heterocyclic compounds, such as pyrrole compounds, pyrazole compounds, imidazole compounds, triazole compounds, tetrazole compounds, pyridine compounds, pyrazine compounds, pyridazine compounds, pyrimidine compounds, indolizine compounds, indole compounds, isoindole compounds, indazole compounds, purine compounds, quinolizine compounds, quinoline compounds, isoquinoline compounds, naphthyridine compounds, phthalazine compounds, quinoxaline compounds, quinazoline compounds, cinnoline compounds, Buterizine compounds, thiazole compounds, isothiazole compounds, oxazole compounds, isoxazole compounds, and furazan compounds. Specific examples of the pyrazole compounds include 1H-pyrazole, 4-nitro-3-pyrazole carboxylic acid, and 3,5-pyrazole carboxylic acid. Specific examples of the imidazole compounds include imidazole, 1-methylimidazole, 2-methylimidazole, 4-methylimidazole, 1,2-dimethylpyrazol, 2-ethyl-4-methylimidazole, 2-isopropylimidazole, benzimidazole, 5,6-dimethylbenzimidazole, 2-aminobenzimidazole, 2-chlorobenzimidazole, and 2-methylbenzimidazole. Specific examples of the triazole compounds include 1,2,3-triazole, 1,2,4-triazole, 1-methyl-1,2,4-triazole, methyl-1H-1,2,4-triazole-3-carboxylate, 1,2,4-triazole-3-carboxylic acid, 1,2,4-triazole-3-methyl carboxylate, 3-amino-1H-1,2,4-triazole, 3-amino-5-benzyl-4H-1,2,4-triazole, 3-amino-5-methyl-4H-1,2,4-triazole, 3-nitro-1,2,4-triazole, 3-bromo-5-nitro-1,2,4-triazole, 4-(1,2,4-triazol-1-yl)phenol, 4-amino-1,2,4-triazole, 4-amino-3,5-dipropyl-4H-1,2,4-triazole, 4-amino-3,5-dimethyl-4H-1,2,4-triazole, 4-amino-3,5-diheptyl-4H-1,2,4-triazole, 5-methyl-1,2,4-triazole-3,4-diamine, 1-hydroxybenzotriazole, 1-aminobenzotriazole, 1-carboxybenzotriazole, 5-chloro-1H-benzotriazole, 5-nitro-1H-benzotriazole, 5-carboxy-1H-benzotriazole, 5,6-dimethyl-1H-benzotriazole, and 1-(1″,2′-dicarboxy ethyl)benzotriazole. Specific examples of the tetrazole compounds include 1H-tetrazole, 5-methyltetrazole, 5-aminotetrazole, and 5-phenyltetrazole. Specific examples of the indole compounds include 1H-indole, 1-methyl-1H-indole, 2-methyl-1H-indole, 3-methyl-1H-indole, 4-methyl-1H-indole, 5-methyl-1H-indole, 6-methyl-1H-indole, and 7-methyl-1H-indole. Specific examples of the indazole compounds include 1H-indazole and 5-amino-1H-indazole. Since these heterocyclic compounds have high chemical or physical adsorbability to the phase-change alloy, they form a stronger protective film on the phase-change alloy surface. For this reason, excessive etching of the phase-change alloy after polishing with the polishing composition is suppressed, and excessive polishing of the phase-change alloy is suppressed.

The content of the metal corrosion inhibitor in the polishing composition is preferably 0.001% by mass or more, more preferably 0.01% by mass or more, further preferably 0.1% by mass or more. As the content of the metal corrosion inhibitor increases, excessive etching of the phase-change alloy after polishing with the polishing composition is suppressed, and excessive polishing of the phase-change alloy is suppressed.

The content of the metal corrosion inhibitor in the polishing composition is preferably 10% by mass or less, more preferably 5% by mass or less, further preferably 1% by mass or less. As the content of the metal corrosion inhibitor decreases, there is an effect of increasing the polishing rate of the phase-change alloy by the polishing composition.

The present embodiment provides the following operation and advantage.

The ionic additive contained in the polishing composition of the present embodiment is bound or adsorbs to the surface of both or either of a phase-change alloy contained in an object to be polished and defective foreign matter to adjust the charge of the phase-change alloy surface and the defective foreign matter surface to the same sign (positive versus positive, or negative versus negative) to thereby cause a repulsive force to act between the phase-change alloy surface and the defective foreign matter surface. For this reason, in the polishing of the object containing the phase-change alloy, the polishing composition of the present embodiment suppresses deposition and residue of defective foreign matter produced from a pad, a polishing apparatus environment, and the polishing composition on the object before or during polishing.

The above embodiment may be modified as follows.
The polishing composition of the above embodiment may contain two or more types of ionic additives. In this case, all the ionic additives need not to have the same sign of potential as long as the surfaces of the phase-change alloy in the object to be polished and the defective foreign matter may carry the same sign of potential as a result.
The polishing composition of the above embodiment may optionally further contain known additives such as a surfactant, a water-soluble polymer, and a preservative that are not classified into ionic additives.
The polishing composition of the above embodiment may be of a one-agent type or may be of a multi-agent type, such as a two-agent type.
The polishing composition of the above embodiment may be prepared by diluting a stock solution of the polishing composition with water.

Next, examples of the present invention and comparative examples will be described.

Polishing compositions of Examples 1 to 27 and Comparative Examples 3 to 6 were prepared by mixing colloidal silica and an ionic additive with water and adding an inorganic acid as a pH adjuster to adjust the value of pH to about 3.0. Polishing composition of Comparative Example 1 that does not contain an ionic additive was prepared by mixing colloidal silica with water and adding an inorganic acid as a pH adjuster to adjust the value of pH to about 3.0. Polishing composition of Comparative Example 2 was prepared by mixing colloidal silica and an oxidizing agent with water and adding an inorganic acid as a pH adjuster to adjust the value of pH to about 3.0. The details of the ionic additives in each polishing composition are as shown in Table 1. Although not shown in Table 1, the colloidal silica in each of the polishing compositions of Examples 1 to 27 and Comparative Examples 1 to 6 had an average primary particle size of 35 nm and an average secondary particle size of about 70 nm (an average degree of association of 2), and the content of the colloidal silica in each polishing composition was 0.5% by mass. Further, the polishing composition of Comparative Example 2 contained 0.3% by mass of hydrogen peroxide as an oxidizing agent.

TABLE 1

| | Ionic additive | | |
|---|---|---|---|
| | | Content (% by | Ionic functional |
| | Type | mass) | group |
| Comparative | — | — | — |
| Example 1 | | | |
| Comparative | — | — | — |
| Example 2 | | | |
| Example 1 | Ammonium polyoxyethylene styrenated phenyl ether | 0.1 | O⁻ |
| | sulfate | | |
| Example 2 | Ammonium polyoxyethylene allyl phenyl ether sulfate | 0.1 | O⁻ |
| Example 3 | Ammonium polyoxyethylene lauryl ether sulfate | 0.1 | O⁻ |
| Example 4 | Polyoxyethylene lauryl ether phosphate ester | 0.1 | O⁻ |
| Example 5 | Linear alkylbenzenesulfonic acid | 0.1 | O⁻ |
| Example 6 | Coconut oil fatty acid sarcosine triethanolamine | 0.1 | O⁻ |
| Example 7 | Coconut oil fatty acid methyltaurine sodium | 0.1 | O⁻ |
| Example 8 | Ammonium polyacrylate | 0.1 | O⁻ |
| Example 9 | Styrene-maleic acid copolymer ammonium | 0.1 | O⁻ |
| Example 10 | Lauryl dimethyl ethyl ammonium ethyl sulfate | 0.1 | N⁺ |
| Example 11 | Stearyl dimethyl hydroxyethyl ammonium p- | 0.1 | N⁺ |
| | toluenesulfonate | | |
| Example 12 | Lauryl trimethylammonium chloride | 0.1 | N⁺ |
| Example 13 | Lauryl dimethyl benzyl ammonium chloride | 0.1 | N⁺ |
| Example 14 | Lauryl dimethyl benzyl ammonium chloride | 0.1 | N⁺ |
| Example 15 | Stearyl dimethylaminopropyl amide | 0.1 | N⁺ |
| Example 16 | Chitosan | 0.1 | N⁺ |
| Example 17 | Dicyandiamide diethylenetetramine condensate | 0.1 | N⁺ |
| Example 18 | Polyvinyl amine | 0.1 | N⁺ |
| Example 19 | Polyamine-epichlorohydrin polycondensate | 0.1 | N⁺ |
| Example 20 | Cation-modified polyacrylamide | 0.1 | N⁺ |
| Example 21 | Poly(diallyldimethylammonium chloride) | 0.1 | N⁺ |
| Example 22 | Diallylamine hydrochloride-acrylamide polymer | 0.1 | N⁺ |
| Example 23 | Polyethylene imine (average molecular weight: 600) | 0.1 | N⁺ |
| Example 24 | Polyethylene imine (average molecular weight: 1,800) | 0.1 | N⁺ |
| Example 25 | Cation-modified hydroxyethyl cellulose | 0.1 | N⁺ |
| Example 26 | Cation-modified polyvinyl alcohol (average molecular | 0.1 | N⁺ |
| | weight: 80,000) | | |
| Example 27 | Lauryl dimethyl aminoacetic acid betaine | 0.1 | N⁺ |
| Comparative | Polyoxyethylene nonyl propenyl phenyl ether | 0.1 | — |
| Example 3 | | | |
| Comparative | Pullulan | 0.1 | — |
| Example 4 | | | |
| Comparative | Polyvinyl pyrrolidone (average molecular weight: | 0.1 | — |
| Example 5 | 50,000) | | |
| Comparative | Hydroxyethyl cellulose (average molecular weight: | 0.1 | — |
| Example 6 | 25,000) | | |

With respect to the ionic additives used in each of the polishing compositions of Examples 1 to 27 and Comparative Examples 1 to 6, the charge on the surface of each metal of Ge, Sb, and Te after treated with an aqueous solution of each of the ionic additives (concentration: 0.1% by mass, pH: about 3.0) was measured by the method and under the conditions shown in Table 2. The results are each shown in “Ge”, “Sb”, and “Te” columns of the “zeta potential” column of Table 4.

A blanket wafer containing a GST alloy (the mass ratio of Ge, Sb, and Te is 2:2:5) was polished under the conditions shown in Table 3 with each of the polishing compositions of Examples 1 to 27 and Comparative Examples 1 to 6.

A polishing by-product and an organic residue on each wafer after polishing were determined. The determination of the polishing by-product and the organic residue was performed by measuring all the defects on each wafer after polishing with a defect inspection apparatus and specifying and counting the polishing by-product and the organic residue among all the defects with a scanning electron microscope (SEM). The results are shown in the “Polishing by-product” column and the “Organic residue” column of the “Evaluation” column of Table 4. In these evaluation results, “oo” represents the case where each of the number of the polishing by-product and the number of the organic residue is 500 or less; “o” represents the case where each of these numbers is from 501 to 1,000; “Δ” represents the case where each of these numbers is from 1,001 to 10,000; and “x” represents the case where each of these numbers is more than 10,000.

The thicknesses of each wafer before polishing and the thickness of the wafer after polishing for a predetermined period of time under the conditions shown in Table 3 were determined from the measurement of sheet resistance by the direct current four-probe method, and the polishing rate was calculated by dividing the difference between the thicknesses of the wafer before polishing and after polishing by the polishing time. The results are shown in the “Polishing rate” column of the “Evaluation” column of Table 4, wherein “o” represents the case where the calculated value of the polishing rate is 1,000 Å/min or less; “Δ” represents the case where the calculated value is higher than 1,000 Å/min and 2,000 Å/min or less; and “x” represents the case where the calculated value is higher than 2,000 Å/min.

TABLE 2

```
To 100 mL of a 0.1% by mass aqueous solution of an ionic additive
adjusted to a pH of 3.0 was added 1.0 g of a powder of Ge, Sb, or Te,
and the zeta potential of each powder was measured. The movement
speed of particles was measured by the dynamic/electrophoretic light
scattering method, and the zeta potential was determined by the
following Smoluchowski's formula.
      Smoluchowski's formula: ζ = (4-πηU)/ε
      (ζ: zeta potential, η: viscosity of solvent, U: electric mobility,
ε: dielectric constant)
```

TABLE 3

Polisher: One-side CMP polishing apparatus
Polishing pad: Polishing pad made of polyurethane
Polishing pressure: 0.8 psi (≈55 hPa)
Rotational speed of platen: 60 rpm
Polishing composition: Used with continuously fed without
being circulated
Rotational speed of carrier: 60 rpm

TABLE 4

| | | | | | Evaluation | | |
|---|---|---|---|---|---|---|---|
| | Zeta potential (mV) | | | | Polish- | | |
| | | | | Aver- | ing by- | Organic | Polish- |
| | Ge | Sb | Te | age | product | residue | ing rate |
| Comparative | −1 | −7 | −3 | −3.7 | x | x | ∘ |
| Example 1 | | | | | | | |
| Comparative | — | — | — | — | x | x | x |
| Example 2 | | | | | | | |
| Example 1 | −33 | −60 | −62 | −51.7 | ∘ | ∘ | ∘ |
| Example 2 | −27 | −32 | −73 | −44.0 | ∘ | ∘ | ∘ |
| Example 3 | −54 | −43 | −60 | −52.3 | ∘ | ∘ | ∘ |
| Example 4 | −94 | −70 | −94 | −86.0 | ∘∘ | ∘ | ∘ |
| Example 5 | −48 | −73 | −78 | −66.3 | ∘ | ∘ | ∘ |
| Example 6 | −48 | −43 | −50 | −47.0 | ∘ | ∘ | ∘ |
| Example 7 | −43 | −52 | −59 | −51.3 | ∘ | ∘ | ∘ |
| Example 8 | −15 | −32 | −2 | −16.3 | Δ | Δ | ∘ |
| Example 9 | −27 | −34 | −29 | −30.0 | ∘ | ∘ | ∘ |
| Example 10 | 45 | 30 | 41 | 38.7 | ∘∘ | ∘∘ | ∘ |
| Example 11 | 53 | 51 | 56 | 53.3 | ∘∘ | ∘∘ | ∘ |
| Example 12 | 63 | 68 | 54 | 61.7 | ∘∘ | ∘∘ | ∘ |
| Example 13 | 60 | 51 | 34 | 48.3 | ∘∘ | ∘∘ | ∘ |
| Example 14 | 54 | 53 | 55 | 54.0 | ∘∘ | ∘∘ | ∘ |
| Example 15 | 62 | 74 | 99 | 78.3 | ∘∘ | ∘∘ | ∘ |
| Example 16 | 53 | 53 | 55 | 53.7 | ∘∘ | ∘∘ | ∘ |
| Example 17 | 28 | 35 | 28 | 30.3 | ∘ | ∘∘ | ∘ |
| Example 18 | 36 | 68 | 0 | 34.7 | Δ | Δ | ∘ |
| Example 19 | 4 | 25 | 5 | 11.3 | ∘ | ∘ | ∘ |
| Example 20 | 9 | 8 | 5 | 7.3 | ∘ | ∘ | ∘ |
| Example 21 | 21 | 20 | 5 | 15.3 | ∘ | ∘ | ∘ |
| Example 22 | 19 | 54 | 15 | 29.3 | ∘ | ∘ | ∘ |
| Example 23 | 61 | 70 | 37 | 56.0 | ∘∘ | ∘∘ | ∘ |
| Example 24 | 5 | 36 | 5 | 15.3 | ∘ | ∘ | ∘ |
| Example 25 | 4 | 36 | 30 | 23.3 | ∘∘ | ∘∘ | ∘ |
| Example 26 | 14 | 14 | 13 | 13.7 | ∘ | ∘ | ∘ |
| Example 27 | 27 | 20 | 13 | 20.0 | ∘ | ∘ | ∘ |
| Comparative | 16 | 12 | 6 | 11.3 | x | x | ∘ |
| Example 3 | | | | | | | |
| Comparative | — | — | — | — | x | x | ∘ |
| Example 4 | | | | | | | |
| Comparative | — | — | — | — | x | x | ∘ |
| Example 5 | | | | | | | |
| Comparative | — | — | — | — | x | x | ∘ |
| Example 6 | | | | | | | |

As shown in Table 4, it was verified that in the case where the polishing compositions of Examples 1 to 27 were used, the polishing by-product and the organic residue significantly decreased compared with the case where the polishing compositions of Comparative Examples 1 to 6, which do not contain ionic additives, were used.

1. A polishing composition to be used for polishing an object containing a phase-change alloy, wherein the polishing composition contains an ionic additive.

2. The polishing composition according to claim 1, wherein the ionic additive is one or more selected from the group consisting of a cationic surfactant, an anionic surfactant, and an amphoteric surfactant.

3. The polishing composition according to claim 1, wherein the ionic additive is a cationic water-soluble polymer.

4. The polishing composition according to claim 1, wherein the polishing composition contains the ionic additive in a concentration of 0.0001 to 10% by mass.

5. The polishing composition according to claim 1, wherein the phase-change alloy is a germanium-antimony-tellurium alloy.

6. A polishing method comprising:
providing an object containing a phase-change alloy; and
using the polishing composition according to claim 1 to polish a surface of the object.

7. A method for producing a phase-change device, comprising polishing a surface of an object containing a phase-change alloy with the polishing composition according to claim 1.

8. The polishing composition according to claim 2, wherein the polishing composition contains the ionic additive in a concentration of 0.0001 to 10% by mass.

9. The polishing composition according to claim 3, wherein the polishing composition contains the ionic additive in a concentration of 0.0001 to 10% by mass.

10. The polishing composition according to claim 2, wherein the phase-change alloy is a germanium-antimony-tellurium alloy.

11. The polishing composition according to claim 3, wherein the phase-change alloy is a germanium-antimony-tellurium alloy.

12. The polishing composition according to claim 4, wherein the phase-change alloy is a germanium-antimony-tellurium alloy.

13. The polishing composition according to claim 8, wherein the phase-change alloy is a germanium-antimony-tellurium alloy.

14. The polishing composition according to claim 9, wherein the phase-change alloy is a germanium-antimony-tellurium alloy.

15. The polishing method according to claim 6, wherein the phase-change alloy is a germanium-antimony-tellurium alloy.

16. The polishing method according to claim 14, wherein the ionic additive is one or more selected from the group consisting of a cationic surfactant, an anionic surfactant, and an amphoteric surfactant.

17. The polishing method according to claim 14, wherein the ionic additive is a cationic surfactant.

18. The method according to claim 7, wherein the phase-change alloy is a germanium-antimony-tellurium alloy.

19. The method according to claim 17, wherein the ionic additive is one or more selected from the group consisting of a cationic surfactant, an anionic surfactant, and an amphoteric surfactant.

20. The method according to claim 17, wherein the ionic additive is a cationic surfactant.
